(19) United States
(12) Patent Application Publication
(10) Pub. No.: US 2025/0226350 A1
(43) Pub. Date: Jul. 10, 2025

(54) PACKAGING STRUCTURE OF RF FRONT-END MODULE

(71) Applicant: RADROCK (CHONGQING) MICROELECTRONICS CO., LTD., Chongqing (CN)

(72) Inventors: Jianxing Ni, Chongqing (CN); Hualei Wang, Chongqing (CN)

(21) Appl. No.: 19/089,044

(22) Filed: Mar. 25, 2025

Related U.S. Application Data
(63) Continuation of application No. PCT/CN2023/119890, filed on Sep. 20, 2023.

(30) Foreign Application Priority Data
Sep. 29, 2022 (CN) 202211202246.8
Oct. 20, 2022 (CN) 202211289001.3

(51) Int. Cl. H01L 23/00; H01L 23/31; H01L 23/498; H01L 25/18

(52) U.S. Cl. CPC H01L 24/32; H01L 23/315; H01L 24/16; H01L 24/29; H01L 24/33; H01L 24/73; H01L 25/18; H01L 23/498; H01L 2224/16227; H01L 2224/29035; H01L 2224/32057; H01L 2224/32111; H01L 2224/32113; H01L 2224/32225; H01L 2224/33183; H01L 2224/73253

(57) ABSTRACT

The present application belongs to the field of packaging technology, and particularly relates to a packaging structure for an RF front-end module. Through the interaction of the support structure and the first adhesive part arranged on the substrate, a cavity structure is formed between the first filter chip and the first surface of the substrate. Moreover, the first adhesive part does not require excessive area coverage, allowing for material savings. This design ensures the formation of a cavity between the filter chip and the substrate while maintaining cost efficiency, and it also improves the reliability of the packaging structure of an RF front-end module.

### CROSS REFERENCE TO RELATED APPLICATIONS

The present application is a Continuation Application of PCT Application No. PCT/CN2023/119890 filed on Sep. 20, 2023, which claims the benefit of Chinese Patent Application Nos. 202211202246.8, filed on Sep. 29, 2022 and 202211289001.3, filed on Oct. 20, 2022. All the above are hereby incorporated by reference in their entirety.

### TECHNICAL FIELD

The present application belongs to the field of packaging technology, and particularly relates to a packaging structure for a radio frequency (RF) front-end module.

### BACKGROUND

With the continuous development of science and technology, new-generation information technology has played an increasingly important role in various industries. In the field of radio frequency, the technical support provided by chips is particularly critical.

In the RF field, certain chips require a cavity structure between the chip itself and the substrate 10 to ensure optimal functionality or performance. Examples include Surface Acoustic Wave (SAW) filter chips and Bulk Acoustic Wave (BAW) filter chips. For such chips, the packaging design is a crucial step in achieving the aforementioned functionality. There is an urgent need to optimize the packaging design process to ensure the realization of the cavity structure and to guarantee excellent reliability.

### SUMMARY OF THE INVENTION

The present application addresses the technical issue of low reliability in the packaging structure of an RF front-end module in the prior art, and provides a packaging structure of an RF front-end module.

### First Aspect

The embodiment of the present application provides a packaging structure of an RF front-end module, which includes:
a substrate, with a first chip pad mounted on the first surface;
a support structure, formed on the first surface of the substrate;
a first filter chip, mounted on the first surface of the substrate, with a first interconnect bump on the bottom surface of the first filter chip, where the first interconnect bump is connected to the first chip pad;
a first adhesive part, at least partially mounted on the support structure and covering at least part of the side surface of the first filter chip; and
a filling material, which covers the first adhesive part, the first filter chip, and at least part of the support structure, where the first adhesive part blocks the filling material from passing through the gap, forming a cavity structure between the first filter chip and the first surface of the substrate.

Optionally, the first adhesive part covers the side surface of the first filter chip and extends to the top surface of the first filter chip, with the top surface being opposite to the bottom surface.

Optionally, the first adhesive part extends from the support structure to the gap formed between the first filter chip and the support structure.

Optionally, the packaging structure of an RF front-end module also includes:
a second adhesive part, which at least partially covers the top surface of the first filter chip, with the top surface being opposite to the bottom surface.

Optionally, the second adhesive part includes at least two parts mounted at intervals on the top surface of the first filter chip.

Optionally, the packaging structure of an RF front-end module further includes:
a first passive component, which is mounted on the first surface of the substrate; the bottom surface of the first passive component is provided with a first conductive bump, which is connected to a second chip pad on the substrate.

Optionally, the first passive component is mounted adjacent to the first filter chip; the first adhesive part is an ultraviolet (UV) curable adhesive, and the space between the bottom surface of the first passive component and the substrate is filled with the filling material.

Optionally, the space between the bottom surface of the first passive component and the substrate is filled with a dielectric material.

Optionally, the first adhesive part also fills the space between the bottom surface of the first passive component and the substrate.

Optionally, the packaging structure of an RF front-end module further includes:
a third adhesive part, which fills the space between the bottom surface of the first passive component and the substrate.

Optionally, the space between the bottom surface of the first passive component and the substrate is filled with both the first adhesive part and the filling material.

Optionally, the first adhesive part also covers at least part of the side surface of the first passive component.

Optionally, the first adhesive part also at least partially covers the top surface of the first passive component, where the top surface is opposite to the bottom surface of the first passive component.

Optionally, the area of the first adhesive part covering the side surface of the first passive component is less than half of the area of the side surface of the first passive component, and/or the maximum height of the first adhesive part covering the side surface of the first passive component is less than half of the height of the side surface of the first passive component.

Optionally, the first adhesive part covers at least a portion of the side surface of the first passive component and extends to its top surface, where the top surface is opposite to the bottom surface.

Optionally, the first adhesive part is applied using impregnation, brushing, spraying, jet dispensing, or needle dispensing processes.

Optionally, the support structure is a solder mask layer.

Optionally, the first filter chip and the support structure have overlapping projections in the longitudinal direction.

Optionally, a gap is formed between the first filter chip and the support structure.

Optionally, the gap between the first filter chip and the support structure is less than or equal to 10 μm.

Optionally, the first filter chip and the support structure do not have overlapping projections in the longitudinal direction.

Optionally, the height of the support structure is greater than the distance between the bottom surface of the first filter chip and the first surface of the substrate.

Optionally, the packaging structure of an RF front-end module further includes:
a first chip, which is flip-chip mounted on the first surface of the substrate;
and/or a second chip, which is mounted on the first surface of the substrate, with a bonding wire on its top surface, where the bonding wire is connected to a fourth chip pad on the substrate.

Optionally, the first adhesive part at least partially covers the first chip and/or the second chip.

Optionally, the filling material covers the first chip and/or the second chip.

Optionally, the packaging structure of an RF front-end module further includes:
a first chip, which is flip-chip mounted on the second surface of the substrate, where the second surface is opposite to the first surface;
and/or
a second chip, which is mounted on the second surface of the substrate, with a bonding wire on its top surface, where the bonding wire is connected to a fourth chip pad on the second surface of the substrate.

### Second Aspect

This application provides a packaging structure of an RF front-end module, including:
a substrate, with a first chip pad mounted on a first surface;
a support structure, formed on the first surface of the substrate;
a first filter chip, flip-chip mounted on the first surface of the substrate, with a gap formed between the first filter chip and the support structure;
a first passive component, mounted on the first surface of the substrate, with a first conductive bump on its bottom surface, which is connected to a second chip pad on the substrate; and
a first adhesive part, at least partially positioned on the support structure, covering at least part of the side surface of the first filter chip, and filling the space between the bottom surface of the first passive component and the substrate.

### Third Aspect

This application provides a packaging structure of an RF front-end module, which includes:
a substrate, with a first chip pad mounted on a first surface;
a support structure, formed on the first surface of the substrate;
a first filter chip, flip-chip mounted on the first surface of the substrate, with a gap formed between the first filter chip and the support structure;
a first adhesive part, at least partially positioned on the support structure, covering at least part of the side surface of the first filter chip; and
a first passive component, mounted on the first surface of the substrate, with a first conductive bump on its bottom surface, which is connected to a second chip pad on the substrate; the space between the bottom surface of the first passive component and the substrate is filled with a dielectric material.

Optionally, the first passive component is electrically connected to the first filter chip.

### Fourth Aspect

This application provides a packaging structure of an RF front-end module, including:
a substrate, with a first chip pad mounted on a first surface;
a support structure, formed on the first surface of the substrate;
a first filter chip, flip-chip mounted on the first surface of the substrate, with a gap formed between the first filter chip and the support structure;
a first adhesive part, at least partially positioned on the support structure, covering at least part of the side surface of the first filter chip;
a first passive component, mounted on the first surface of the substrate, with a first conductive bump on its bottom surface, which is connected to a second chip pad on the substrate;
a filling material, covering the first adhesive part, the first filter chip, and at least part of the support structure; and
the space between the bottom surface of the first passive component and the substrate is filled with the first adhesive part and the filling material.

### Fifth Aspect

This application provides a packaging structure of an RF front-end module, which includes:
a substrate, with a first chip pad mounted on a first surface;
a support structure, formed on the first surface of the substrate;
a first filter chip, mounted on the first surface of the substrate, with a gap formed between the first filter chip and the support structure; the bottom surface of the first filter chip has a first interconnect bump, which is connected to the first chip pad;
a first adhesive part, at least partially positioned on the support structure, covering at least part of the side surface of the first filter chip;
a first passive component, mounted on the first surface of the substrate, adjacent to the first filter chip; the bottom surface of the first passive component has a first conductive bump, which is connected to a second chip pad on the substrate; the space between the bottom surface of the first passive component and the substrate is filled with first barrier material; and
a second passive component, mounted on the first surface of the substrate, positioned away from the first filter chip; the bottom surface of the second passive component has a second conductive bump, which is connected to a third chip pad on the substrate; the space between the bottom surface of the second passive component and the substrate is filled with second barrier material.

Optionally, the first barrier material and the second barrier material are different materials.

Optionally, the packaging structure of an RF front-end module further includes a filling material, covering the first adhesive part, the first filter chip, the first passive component, the second passive component, and at least part of the support structure.

Optionally, the first adhesive part is an ultraviolet (UV) curable adhesive, and the first barrier material and second barrier material is the filling material.

Optionally, the first barrier material is a dielectric material, the second barrier material is the filling material.

Optionally, the first barrier material is the first adhesive part, the second barrier material is the filling material.

Optionally, the first passive component and/or second passive component are surface-mounted devices.

Optionally, the packaging structure of an RF front-end module further includes:
a first chip, flip-chip mounted on the first surface of the substrate;
and/or
a second chip, mounted on the first surface of the substrate, with a bonding wire on its top surface, which is connected to a fourth chip pad on the substrate.

Optionally, the first adhesive part covers the first filter chip, the first chip, the first passive component, and the second passive component.

### Sixth Aspect

This application provides a packaging structure of an RF front-end module, which includes:
a substrate, with a first chip pad mounted on a first surface;
a support structure, formed on the first surface of the substrate;
a first filter chip, mounted on the first surface of the substrate, with a gap formed between the first filter chip and the support structure; the bottom surface of the first filter chip has a first interconnect bump, which is connected to the first chip pad;
a first passive component, mounted on the first surface of the substrate, positioned at a distance d1 from the first filter chip; the bottom surface of the first passive component has a first conductive bump, which is connected to a second chip pad on the substrate; the space between the bottom surface of the first passive component and the substrate is filled with a first barrier material;
a first adhesive part, at least partially positioned on the support structure, covering at least part of the side surface of the first filter chip, and filling the space between the bottom surface of the first passive component and the substrate;
a third passive component, mounted on the first surface of the substrate, positioned at a distance d3 from the first filter chip; the bottom surface of the third passive component has a third conductive bump, which is connected to a fourth chip pad on the substrate; the space between the bottom surface of the third passive component and the substrate is filled with a dielectric material; and
where d3≥d1.

Optionally, the packaging structure of an RF front-end module further includes:
a second passive component, mounted on the first surface of the substrate, positioned at a distance d2 from the first filter chip; the bottom surface of the second passive component has a second conductive bump, which is connected to a third chip pad on the substrate; the space between the bottom surface of the second passive component and the substrate is filled with a filling material; and
where d2>d3.

Optionally, the first barrier material is part of the first adhesive part, or the first barrier material is a dielectric material.

Optionally, d1<150 μm, and/or d3<200 μm.

Optionally, d2>200 μm.

### Seventh Aspect

This application embodiment provides a packaging structure of an RF front-end module, which includes:
a substrate, including a first surface and a second surface, where the first surface is opposite to the second surface;
a first support structure, formed on the first surface of the substrate;
a second support structure, formed on the second surface of the substrate;
at least one first filter chip, flip-chip mounted on the first surface of the substrate;
a first adhesive part, at least partially set on the first support structure and covering at least part of at least one first filter chip's side surface;
at least one second filter chip, flip-chip mounted on the second surface of the substrate; and
a first passive component, mounted on the substrate, positioned near any first filter chip or second filter chip; the bottom surface of the first passive component is provided with a first conductive bump, which is connected to a second chip pad on the substrate. a first barrier material is filled between the bottom surface of the first passive component and the substrate.

Optionally, the packaging structure of an RF front-end module also includes:
a second passive component, mounted on the substrate and positioned away from any first filter chip and second filter chip; the bottom surface of the second passive component is provided with a second conductive bump, which is connected to a third chip pad on the substrate. a second barrier material is filled between the bottom surface of the second passive component and the substrate.

Optionally, the first adhesive part is an ultraviolet (UV) curable adhesive, and the first barrier material and second barrier material are filling materials.

Optionally, the first barrier material is a dielectric material, the second barrier material is a filling material.

Optionally, the first barrier material is the first adhesive part, the second barrier material is a filling material.

Optionally, the packaging structure of an RF front-end module further includes:
a first chip, flip-chip mounted on the first surface or second surface of the substrate;
and/or,
a second chip, mounted on the first surface or second surface of the substrate; the top surface of the second chip is provided with bonding wire, which connects to a fourth chip pad on the substrate.

Optionally, the first adhesive part at least partially covers the first chip and/or second chip.

Optionally, the first filter chip is a surface acoustic wave (SAW) filter chip or a bulk acoustic wave (BAW) filter chip; and/or the second filter chip is a SAW filter chip or a BAW filter chip.

In the embodiment of the present application, the packaging structure of the RF front-end module ensures the formation of a cavity structure between the first filter chip and the first surface of the substrate through the interaction between the support structure and the first adhesive part arranged on the substrate. Moreover, the first adhesive part does not require excessive area coverage, allowing for material savings. This design ensures the formation of a cavity between the filter chip and the substrate while maintaining cost efficiency, and it also improves the reliability of the packaging structure of an RF front-end module.

The details of one or more embodiments of the present application are set forth in the following drawings and description. Other features and advantages of the present application will become apparent from the specification, drawings, and claims.

### BRIEF DESCRIPTION OF THE DRAWINGS

To clearly illustrate the technical solutions of the embodiments of this application, the following briefly introduces the accompanying drawings used in the description of the embodiments. Obviously, the drawings in the following description are only some embodiments of this application. For those skilled in the art, other drawings can be obtained based on these drawings without creative effort.

FIG. 1 is a schematic diagram of the packaging structure of an RF front-end module in at least one embodiment of the present application.

FIG. 2 is a schematic diagram of the packaging structure of an RF front-end module in another embodiment of the present application.

FIG. 3 is a schematic diagram of the packaging structure of an RF front-end module in another embodiment of the present application.

FIG. 4 is a schematic diagram of the packaging structure of an RF front-end module in another embodiment of the present application.

FIG. 5 is a schematic diagram of the packaging structure of an RF front-end module in another embodiment of the present application.

FIG. 6 is a schematic diagram of the packaging structure of an RF front-end module in another embodiment of the present application.

FIG. 7 is a schematic diagram of the packaging structure of an RF front-end module in another embodiment of the present application.

FIG. 8 is a schematic diagram of the packaging structure of an RF front-end module in another embodiment of the present application.

FIG. 9 is a schematic diagram of the packaging structure of an RF front-end module in another embodiment of the present application.

FIG. 10 is a schematic diagram of the packaging structure of an RF front-end module in another embodiment of the present application.

FIG. 11 is a schematic diagram of the packaging structure of an RF front-end module in another embodiment of the present application.

FIG. 12 is a schematic diagram of the packaging structure of an RF front-end module in another embodiment of the present application.

FIG. 13 is a schematic diagram of the packaging structure of an RF front-end module in another embodiment of the present application.

FIG. 14 is a schematic diagram of the packaging structure of an RF front-end module in another embodiment of the present application.

FIG. 15 is a schematic diagram of the packaging structure of an RF front-end module in another embodiment of the present application.

FIG. 16 is a schematic diagram of the packaging structure of an RF front-end module in another embodiment of the present application.

FIG. 17 is a schematic diagram of the packaging structure of an RF front-end module in another embodiment of the present application.

### DETAILED DESCRIPTION OF PREFERRED EMBODIMENTS

The technical solutions in the embodiments of the present application will be clearly and completely described below with reference to the drawings in the embodiments of this application. Obviously, the described embodiments are merely part of the embodiments of this application, not all of them. Based on the embodiments in this application, all other embodiments obtained by those of ordinary skill in the art without creative effort belong to the protection scope of this application.

It should be understood that the exemplary embodiments may be embodied in many different forms and should not be construed as being limited to the exemplary embodiments set forth herein. Rather, these embodiments are provided so that this disclosure will be thorough and complete, and will fully convey the protection scope of this application to those skilled in the art. In the drawings, like reference signs refer to like elements throughout, and the size and relative sizes of layers and regions may be exaggerated for clarity.

It should be understood that when an element or layer is referred to as being “on”, “adjacent to”, “connected to”, “coupled to”, “attached to”, or “linked to” another element or layer, it can be directly on, adjacent to, connected to, coupled to, or linked to the other element or layer, or intervening elements or layers may be present. Conversely, when an element is referred to as being “directly on”, “directly adjacent to”, “directly connected to” or “directly coupled to” another element or layer, there are no intervening elements or layers present. It should also be understood that although terms such as “first”, “second”, “third” etc., may be used to describe various elements, components, regions, layers, and/or parts, these elements, components, regions, layers, and/or parts should not be limited by these terms. These terms are used only to distinguish one element, component, region, layer, or part from another. Thus, without departing from the teachings of this application, a first element, component, region, layer, or part discussed below could be termed a second element, component, region, layer, or part.

Spatial terms such as “below”, “under”, “down”, “above”, “on” and “up” may be used here for convenience of description to describe the relationship between one element or feature and other elements or features shown in the figures. It should be understood that in addition to the orientations shown in the figures, the spatial relationship terms are intended to include different orientations of devices in use and operation. For example, if the device in the figures is turned upside down, then the elements or features described as “below” or “under” other elements or features would be “above” or “on” other elements or features. Therefore, the exemplary terms “below” or “under” may include the orientations of “above” or “on”. The device may be otherwise oriented (rotated by 90 degrees or other orientations) and the spatial description terms used here are interpreted accordingly.

The terms used here are only for the purpose of describing specific embodiments and not as a limitation of the present application. As used herein, singular forms of “a”, “an” and “the/said” are also intended to include plural forms, unless the context clearly indicates otherwise. It should also be understood that the terms “comprise” and/or “include” used in this specification specify the presence of said features, integers, steps, operations, elements and/or components, but do not exclude the presence or addition of one or more other features, integers, steps, operations, elements, components and/or groups. As used herein, the term “and/or” includes any and all combinations of related listed items.

For a thorough understanding of this application, detailed structures and steps will be set forth in the following description, so as to illustrate the technical solution proposed in the present application. The preferred embodiments of the present application are described in detail as follows, but besides these detailed descriptions, the present application may also have other embodiments.

At least one embodiment of the present application provides a packaging structure for an RF front-end module, including:
a substrate 10, with a first chip 80 pad 12 mounted on a first surface 11;
a support structure 20, formed on the first surface 11 of the substrate 10;
a first filter chip 30, mounted on the first surface 11 of the substrate 10, with a gap formed between the first filter chip 30 and the support structure 20; the bottom surface of the first filter chip 30 is provided with a first interconnect bump 31, the first interconnect bump 31 is connected to the first chip 80 pad 12;
a first adhesive part 40, at least partially mounted on the support structure 20 and covering at least part of the side surface of the first filter chip 30; and
a filling material 50, which covers the adhesive part, the first filter chip 30, and at least part of the support structure 20.

The RF front-end module includes a first filter chip 30, which may optionally be a Surface Acoustic Wave (SAW) filter chip, a Bulk Acoustic Wave (BAW) filter chip, or another type of filter chip that requires a cavity. Furthermore, the RF front-end module may also include at least one of the following components: a power amplifier, a low-noise amplifier, an RF switch, a filter module, or a control circuit. It is understood that the filter module may be implemented in a different manner than the first filter chip 30 or may adopt the same implementation approach. For example, the filter module may be an LC filter, an LTCC filter, or an acoustic wave filter, among others.

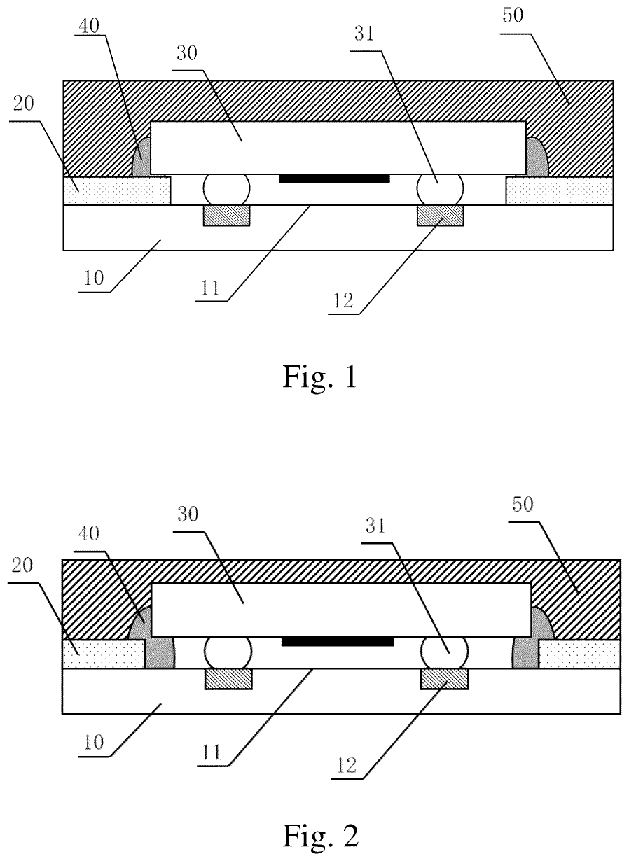

As shown in FIG. 1, the packaging structure of the RF front-end module includes a substrate 10 with a first surface 11. The substrate 10 may be a resin substrate 10, ceramic substrate 10, glass substrate 10, or another type of substrate 10. Optionally, the substrate 10 is a resin substrate 10. The first chip 80 pad 12 is provided on the first surface 11 of the substrate 10. The first chip 80 pad 12 mounted on the first surface 11 can be arranged on the first surface 11 of the substrate 10 (i.e., protruding from the first surface 11). Alternatively, the first chip 80 pad 12 can be embedded into the substrate 10 from the first surface 11 (as shown in FIG. 1). Additionally, the first chip 80 pad 12 can be both embedded into the substrate 10 and protrude above the first surface 11, or other feasible configurations of the first chip 80 pad 12 are also possible, which are not specifically limited here. In this embodiment, the first chip 80 pad 12 is described as being mounted on the first surface 11. As shown in FIG. 1, the first surface 11 of the substrate 10 may include one or more first chip 80 pads 12.

The support structure 20 is formed on the first surface 11 of the substrate 10. In at least one implementation, the support structure 20 is a solder mask layer, which is made of solder mask material. In this implementation, the support structure 20 is directly formed as a solder mask layer on the first surface 11 of substrate 10. By utilizing the solder mask layer as the support structure 20, the need for additional layers is reduced, leading to savings in materials and processing costs.

The first filter chip 30 is arranged on the first surface 11 of the substrate 10, and the bottom surface is provided with a first interconnect bump 31, which connects to the first chip 80 pad 12. In at least one implementation, there may be two or more first interconnect bumps 31 on the bottom of the first filter chip 30. In at least one implementation, the number of first interconnect bumps 31 is the same as that of first chip 80 pads 12. In at least one implementation, the first interconnect bumps 31 can be made of copper, tin, gold, alloys, or other commonly used materials. In at least one implementation, the support structure 20 includes an opening that exposes the first surface 11 of the substrate 10. The first filter chip 30 may be at least partially arranged over this opening. As shown in FIG. 1, the majority of the first filter chip 30 is arranged over the opening, while a smaller portion arranged on the support structure 20. In this case, the vertical projections of the first filter chip 30 and the support structure 20 may overlap. In this implementation, the first filter chip 30 can either be in direct contact with the support structure 20 or form a gap with the support structure 20.

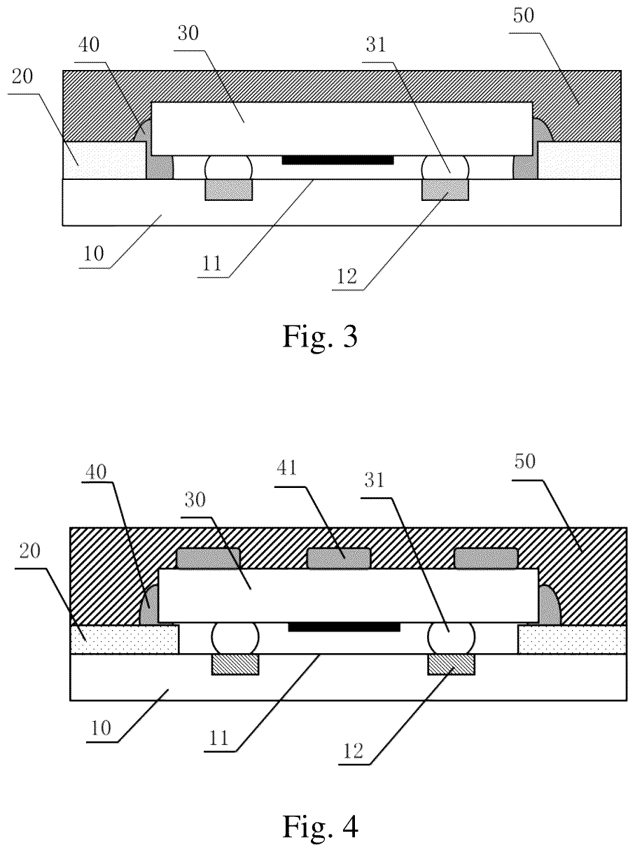

In at least one implementation, as shown in FIG. 2 or 3, the first filter chip 30 is fully arranged over the opening. In this case, there is no overlap in the vertical projection between the first filter chip 30 and the support structure 20. In at least one implementation, the lateral distance between the first filter chip 30 and the support structure 20 is less than 50 μm. Furthermore, the lateral distance between the first filter chip 30 and the support structure 20 is less than 20 μm.

In at least one embodiment, the height of the support structure 20 is greater than the distance from the bottom surface of the first filter chip 30 to the first surface 11. As shown in FIG. 3, the height of the support structure 20 is greater than the distance from the bottom surface of the first filter chip 30 to the first surface 11. In at least one implementation, the first adhesive part 40 extends from the support structure 20 to the first surface 11 of the substrate 10. As shown in FIG. 3, the first adhesive part 40 extends from the support structure 20 along the gap between the first filter chip 30 and the support structure 20 to the first surface 11 of substrate 10. In at least one implementation, the first adhesive part 40 extends from the support structure 20 to the gap between the first filter chip 30 and the support structure 20. In at least one implementation, the material of the first interconnect bump 31 is gold. It is understood that the surface of the first chip 80 pad 12 may be made of materials such as gold or silver, which can easily form interconnections with gold.

In at least one implementation, a gap is formed between the first filter chip 30 and the support structure 20. It is understood that the vertical projection of the first filter chip 30 and the support structure 20 may either overlap or not overlap. For example, as shown in FIG. 1, the vertical projections of the first filter chip 30 and the support structure 20 overlap. It is understood that the vertical projections of the first filter chip 30 and the support structure 20 may overlap, and this overlapping area may be continuous or discontinuous. Alternatively, the overlapping area may form a closed shape or an open shape. For example, the overlapping area could be a closed rectangular ring-shaped structure, or a structure with an opening. In other words, the overlapping projection in the vertical direction between the first filter chip 30 and the support structure 20 can be at least partially in the outer side of the bottom surface of the first filter chip 30 and overlap with the vertical projection of the support structure 20. In one implementation, as shown in FIG. 2 or 3, the vertical projections of the first filter chip 30 and the support structure 20 do not overlap.

In at least one implementation, the vertical projection of the first filter chip 30 and the support structure 20 overlaps. In at least one implementation, the gap formed between the filter chip and the support structure 20 is less than or equal to 20 μm. Furthermore, the gap formed between the filter chip and the support structure 20 is less than or equal to 10 μm. In at least one implementation, the gap formed between the filter chip and the support structure 20 is less than or equal to 5 μm. It is understood that this gap refers to the vertical distance between the bottom surface of the filter chip and the upper surface of the support structure 20.

The first adhesive part 40 is at least partially arranged on the support structure 20 and covers at least part of the side surface of the first filter chip 30. As shown in FIG. 1, the first adhesive part 40 is arranged on the support structure 20 and covers at least part of the side surface of the first filter chip 30. The first adhesive part 40 is at least partially arranged on the support structure 20. Optionally, the first adhesive part 40 may also include a portion arranged on the first surface 11 of the substrate 10, meaning that the first adhesive part 40 extends from the support structure 20 to the first surface 11 of the substrate 10. As shown in FIG. 2, the first adhesive part 40 extends from the support structure 20 along the gap between the first filter chip 30 and the support structure 20 to the first surface 11 of the substrate 10. It is understood that the first adhesive part 40 may also extend from the support structure 20 along the horizontal direction away from the first filter chip 30 toward the first surface 11 of the substrate 10. In at least one implementation, the first adhesive part 40 is entirely arranged on the support structure 20.

As shown in FIGS. 1-2, the first adhesive part 40 also covers at least part of the side surface of the first filter chip 30. In at least one implementation, the first adhesive part 40 covers the lower half of the side surface of the first filter chip 30. By controlling the first adhesive part 40 to cover only the lower half of the side surface of the first filter chip 30, excessive adhesive usage is avoided, preventing the first adhesive part 40 from flowing to other areas and affecting other components. In at least one implementation, the first adhesive part 40 also covers at least part of the upper half of the side surface of the first filter chip 30. In at least one implementation, the first adhesive part 40 fully covers the side surface of the first filter chip 30.

The first adhesive part 40 may be made of an insulating curable material. For example, the first adhesive part 40 may be made of insulating glue, insulating ink, or other materials such as resin-based insulating adhesive. In at least one implementation, the first adhesive part 40 may be made primarily of an insulating liquid polymer material. In at least one implementation, the first adhesive part 40 may use a fast-curing adhesive (e.g., UV-curable adhesive). It is understood that in other implementations, the first adhesive part 40 may also use other commonly used adhesives or materials with similar properties (insulating and curable). The first adhesive part 40 may be applied using dipping, brushing, spray coating, jetting dispense, needle dispense, or printing processes.

The filling material 50 covers the first adhesive part 40, the first filter chip 30, and at least part of the support structure 20. The filling material 50 may be made of an insulating resin material or other conventional encapsulation materials. Optionally, the filling material 50 is a resin material containing particles. These particles may be silicon dioxide (SiO₂) or aluminum oxide (Al₂O₃) particles, but the embodiments of this application are not limited to these. It is understood that other materials capable of achieving a sealing function may also be used and will not be further detailed here.

As shown in FIGS. 1-2, a cavity structure is formed between the first filter chip 30 and the first surface 11 of the substrate 10. In at least one implementation, the first adhesive part 40 prevents the filling material 50 from passing through the gap or other channels, thereby ensuring the formation of the cavity structure between the first filter chip 30 and the substrate 10.

In at least one implementation, the cavity structure formed between the first filter chip 30 and the substrate 10 may specifically be formed by the bottom surface of the first filter chip 30, the support structure 20, and the first surface 11 of the substrate 10. Alternatively, the cavity structure between the first filter chip 30 and the substrate 10 may be specifically formed by the bottom surface of the first filter chip 30, the support structure 20, the first adhesive part 40, and the first surface 11 of the substrate 10. In at least one implementation, the cavity structure may be formed between the first filter chip 30 and the first surface 11 of the substrate 10. Alternatively, in the cavity structure, a support structure 20 may also be provided on a portion of the first surface 11 of the first substrate 10, meaning that in areas outside the first pad 12 on the first surface 11, at least a portion of the support structure 20 may be present.

This embodiment ensures the formation of a cavity structure between the first filter chip 30 and the first surface 11 of the substrate 10 through the interaction between the support structure 20 and the first adhesive part 40 arranged on the substrate 10. Moreover, the first adhesive part 40 does not require excessive area coverage, allowing for material savings. This design ensures the formation of a cavity between the filter chip and the substrate 10 while maintaining cost efficiency, and it also improves the reliability of the packaging structure of an RF front-end module.

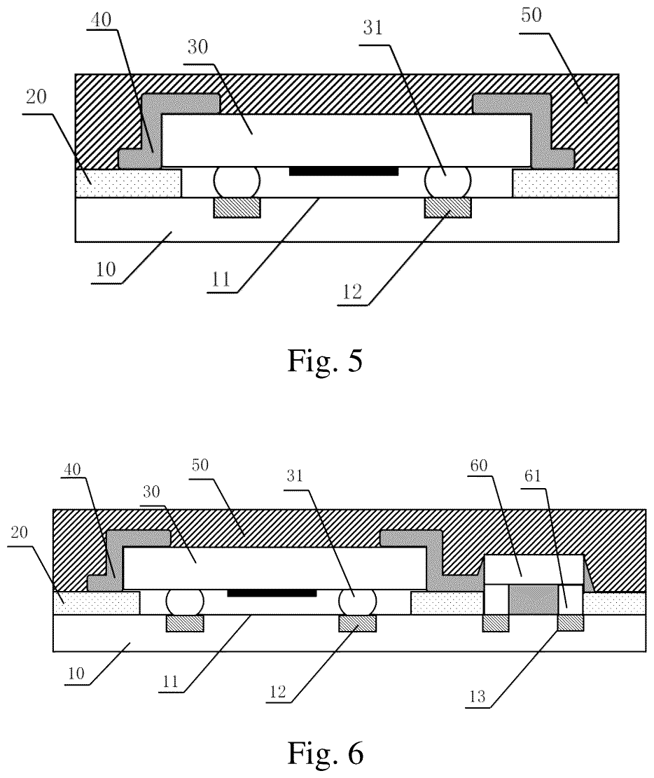

In at least one embodiment, the first adhesive part 40 covers at least a portion of the side surface of the first filter chip 30 and extends to the top surface of the first filter chip 30, where the top surface is opposite to the bottom surface of the first filter chip 30. As shown in FIG. 5, the first adhesive part 40 not only covers the side surface of the first filter chip 30 but also extends from the side surface to the top surface of the first filter chip 30. It can be understood that the first adhesive part 40 may partially cover the top surface of the first filter chip 30 or may completely cover it. By also arranging the first adhesive part 40 on the top surface of the first filter chip 30, the risk of cracking in the chip, the first interconnect bump 31, and/or the first chip 80 pad 12 due to stress during the subsequent formation of the filling material 50 is reduced, thereby improving the reliability of the overall packaging structure.

In at least one embodiment, the first adhesive part 40 extends from the support structure 20 into the gap formed between the first filter chip 30 and the support structure 20. Due to the inherent flowability of the first adhesive part 40, a portion of the first adhesive part 40 also enters the gap formed between the first filter chip 30 and the support structure 20, further enhancing its blocking effect and ensuring better cavity structure formation.

In at least one embodiment, the packaging structure of an RF front-end module further includes:

a second adhesive part 41 that at least partially covers the top surface of the first filter chip 30, where the top and bottom surfaces are opposite. As shown in FIG. 4, the second adhesive part 41 is included on the top surface of the first filter chip 30. The second adhesive part 41 may partially cover or completely cover the top surface of the first filter chip 30. It can be understood that the second adhesive part 41 may be made of a different material than the first adhesive part 40 and/or may be applied at different process stages. Alternatively, the second adhesive part 41 may be made of the same material as the first adhesive part 40 and/or be applied in the same process stage.

In at least one embodiment, the second adhesive part 41 includes at least two portions that are arranged at intervals on the top surface of the first filter chip 30. That is, the second adhesive part 41 may be discontinuously arranged on the top surface of the first filter chip 30. In other words, the second adhesive part 41 consists of multiple separate portions, each distributed at different positions on the top surface of the first filter chip 30. Exemplarily, these portions may be positioned in the middle, at the edges, or between the middle and edges of the top surface. In this case, the second adhesive part 41 may include more than two separate portions, which are positioned at different positions on the top surface of the first filter chip 30. Taking FIG. 4 as an example, the second adhesive part 41 in FIG. 4 consists of three separate portions spaced apart at different positions on the top surface of the first filter chip 30. By also arranging the second adhesive part 41 on the top surface of the first filter chip 30, the risk of cracking in the chip, the first interconnect bump 31, and/or the first chip 80 pad 12 due to stress during the subsequent formation of the filling material 50 is reduced, thereby improving the reliability of the overall packaging structure. Furthermore, by configuring the second adhesive part 41 as at least two spaced-apart portions on the top surface of the first filter chip 30, both material cost efficiency and stress relief advantages can be achieved.

In at least one embodiment, as shown in FIG. 6, the packaging structure of an RF front-end module further includes:

a first passive component 60, arranged on the first surface 11 of the substrate 10. The bottom surface of the first passive component 60 is arranged with a first conductive bump 61, which connects to the second chip 90 pad 13 on the substrate 10. In at least one embodiment, the first conductive bump 61 may be solder paste or other commonly used conductive bump materials in the field.

The first passive component 60 may be a passive element. For example, it may be a capacitor, an inductor, or a resistor. As shown in FIG. 6, the first passive component 60 is arranged on the first surface 11 of the substrate 10.

The second chip 90 pad 13 arranged on the first surface 11 may be positioned above the first surface 11 of the substrate 10 (i.e., protruding from the first surface 11), embedded within the first surface 11 (as shown in FIG. 1), or embedded in the first surface 11 while also protruding above it, among other feasible arrangements of the first chip 80 pad 12. These configurations are not specifically limited here. In this embodiment, the second chip 90 pad 13 is arranged on the first surface 11, and as shown in FIG. 1, one or more second chip 90 pads 13 may be included on the first surface 11 of the substrate 10.

The bottom surface of the first passive component 60 is provided with one or more first conductive bumps 61. It is understood that the first conductive bumps 61 correspond to the second chip 90 pads 13. In at least one embodiment, the number of first conductive bumps 61 is equal to the number of second chip 90 pads 13.

In at least one embodiment, the first passive component 60 is electrically connected to the first filter chip 30. The electrical connection between the first passive component 60 and the first filter chip 30 may be achieved through wiring on the substrate 10 or through wire bonding, among other methods.

In at least one embodiment, the first passive component 60 may be a passive element in a matching network. For example, the matching network may be used for impedance matching of the input or output of the first filter chip 30.

In at least one embodiment, the first passive component 60 is arranged near the first filter chip 30. By arranging the first passive component 60 close to the filter, the wiring distance for electrical connection between them is reduced, effectively minimizing parasitic effects introduced by excessive wiring length or interference from other components along the wiring path. Specifically, the first passive component 60 being arranged near the first filter chip 30 may mean that it is positioned around the first filter chip 30, positioned closer to the first filter chip 30 compared to other passive components, or positioned closer to the filter chip compared to other chips.

In at least one embodiment, the spacing between the first passive component 60 and the first filter chip 30 is less than 150 μm, 100 μm, or 80 μm.

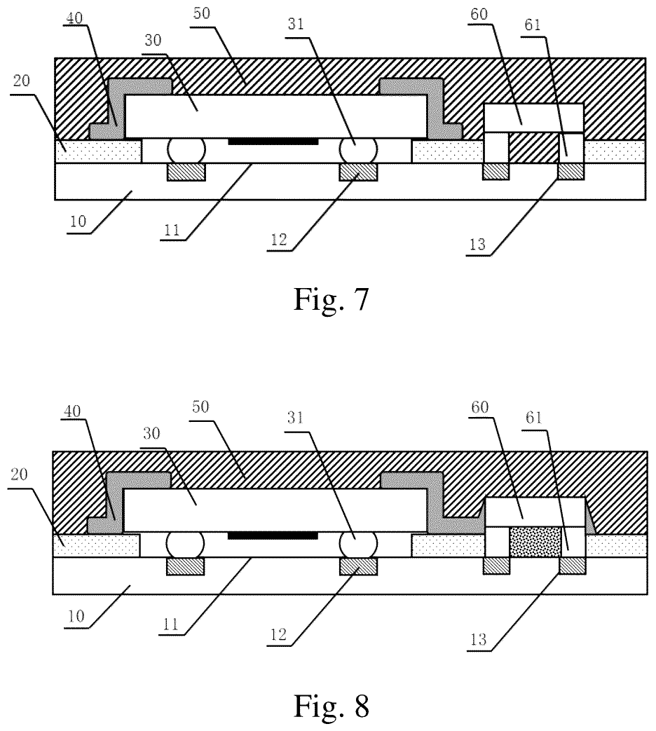

In at least one embodiment, as shown in FIG. 7, the first passive component 60 is arranged near the first filter chip 30, and the first adhesive part 40 is a fast-curing adhesive. The space between the bottom surface of the first passive component 60 and the substrate 10 is filled with a filling material 50. In at least one embodiment, the fast-curing adhesive is a UV-curable adhesive.

In this embodiment, by arranging the first passive component 60 near the first filter chip 30 and using a fast-curing adhesive as the first adhesive part 40, the adhesive can be quickly cured after application. This prevents the first adhesive part 40 from covering the first passive component 60 arranged near the first filter chip 30. As a result, during the subsequent filling material 50 application, the filling material 50 can smoothly enter the space between the bottom surface of the first passive component 60 and the substrate 10, ensuring proper filling. This prevents unintended interconnections caused by melting of different first conductive bump 61s in the first passive component 60 during later processing or application, thereby improving the reliability of the first passive component 60.

In at least one embodiment, as shown in FIG. 8, the space between the bottom surface of the first passive component 60 and the substrate 10 is filled with a dielectric material 70. That is, a dielectric material 70 is arranged in the space between the bottom surface of the first passive component 60 and the substrate 10. The applicant has discovered during the design process that when arranging the first adhesive part 40, it may easily extend to cover the first passive component 60 or form a blockage, potentially preventing or making it difficult for the filling material 50 to enter the space between the bottom surface of the first passive component 60 and the substrate 10. This may result in a persistent gap, passage, or space between the first passive component 60 and the substrate 10 in the packaging structure of an RF front-end module. During subsequent processing or use, the connection between the first conductive bump 61 of the first passive component 60 and the second chip 90 pad 13 may melt, leading to unintended interconnections between different first conductive bump 61s, ultimately causing device failure. In this embodiment, the dielectric material 70 may be arranged on the first surface 11 of the substrate 10 first, followed by the mounting of the first passive component 60. Therefore, by filling the space between the bottom surface of the first passive component 60 and the substrate 10 with a dielectric material 70, the probability of the above issues occurring is reduced, further enhancing the reliability of the packaging structure of an RF front-end module.

In at least one embodiment, the dielectric material 70 may be implemented using an adhesive with low fluidity.

In at least one embodiment, the first adhesive part 40 at least partially fills the space between the bottom surface of the first passive component 60 and the substrate 10. In this embodiment, since the first passive component 60 is arranged near the first filter chip 30, the first adhesive part 40 may flow into the space between the bottom surface of the first passive component 60 and the substrate 10 during the application process, thereby partially or completely filling this space. It is understood that the possibility of the first adhesive part 40 flowing into the space between the bottom surface of the first passive component 60 and the substrate 10 can be influenced by adjusting the distance between the first passive component 60 and the first filter chip 30, controlling process parameters (such as temperature, pressure, etc.), or selecting appropriate materials for the first adhesive part 40. In at least one embodiment, as shown in FIG. 6, the first adhesive part 40 fills the space between the bottom surface of the first passive component 60 and the substrate 10.

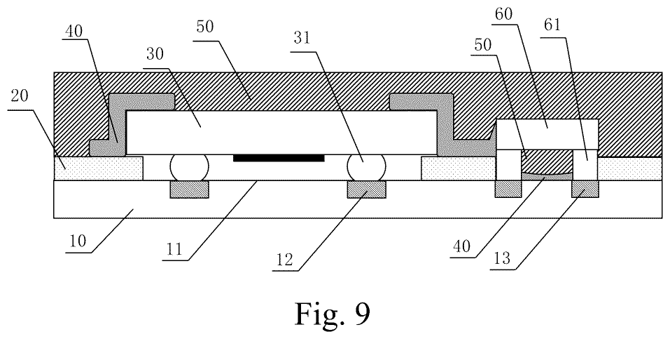

In at least one embodiment, as shown in FIG. 9, the space between the bottom surface of the first passive component 60 and the substrate 10 is filled with both the first adhesive part 40 and a filling material 50. In this embodiment, since the first passive component 60 is arranged near the first filter chip 30, some of the first adhesive part 40 enters the space between the bottom surface of the first passive component 60 and the substrate 10 when the first adhesive part 40 is arranged. Unlike the embodiment shown in FIG. 6, in this embodiment, the first adhesive part 40 does not completely fill the space between the bottom surface of the first passive component 60 and the substrate 10 but only fills part of it. Consequently, when the filling material 50 is subsequently applied, it fills the remaining space between the bottom surface of the first passive component 60 and the substrate 10 that was not filled by the first adhesive part 40. In at least one embodiment, the first adhesive part 40 does not completely cover the side surface of the first passive component 60, or it partially covers the side surface of the first passive component 60. In at least one embodiment, the area of the first adhesive part 40 covering the side surface of the first passive component 60 is less than one-half, one-third, or one-fourth of the total side surface area of the first passive component 60. In at least one embodiment, the maximum height of the first adhesive part 40 covering the side surface of the first passive component 60 is less than one-half, one-third, or one-fourth of the total height of the first passive component 60's side surface.

In this embodiment, the first adhesive part 40 between the bottom surface of the first passive component 60 and the substrate 10, along with the filling material 50, together fill the space between the bottom surface of the first passive component 60 and the substrate 10. Since there is also the first adhesive part 40 between the filling material 50 and the substrate 10, the overall bonding strength is further increased, thereby improving the reliability of the packaging structure of an RF front-end module.

In at least one embodiment, the first adhesive part 40 covers at least part of the side surface of the first passive component 60 and extends to the top surface of the first passive component 60, where the top surface and the bottom surface of the first passive component 60 are opposite to each other.

In this embodiment, the first adhesive part 40 covers at least part of the side surface of the first passive component 60 and extends to the top surface of the first passive component 60. The first adhesive part 40 may cover at least part of the top surface of the first passive component 60, thereby reducing the risk of cracking due to stress in the subsequent first passive component 60.

In at least one embodiment, the packaging structure of an RF front-end module also includes:
a third adhesive part, which fills the space between the bottom surface of the first passive component 60 and the substrate 10.

As shown in FIG. 6, the space between the bottom surface of the first passive component 60 and the substrate 10 is filled with the third adhesive part. In this embodiment, by filling the space between the bottom surface of the first passive component 60 and the substrate 10 with the third adhesive part, the risk of failure of the first passive component 60 is reduced, further improving the reliability of the overall packaging structure. The third adhesive part can be resin glue, UV-curable adhesive, or other commonly used adhesive materials. The third adhesive part can be formed through processes such as dipping, brushing, spraying, jetting dispense, or needle dispense. In at least one implementation, the third adhesive part can be made of the same material as the first adhesive part 40, or it can be made of a different material. In at least one implementation, the third adhesive part and the first adhesive part 40 can be made using the same process, or they can be made using different processes. In at least one implementation, the third adhesive part and the first adhesive part 40 are made using the same process.

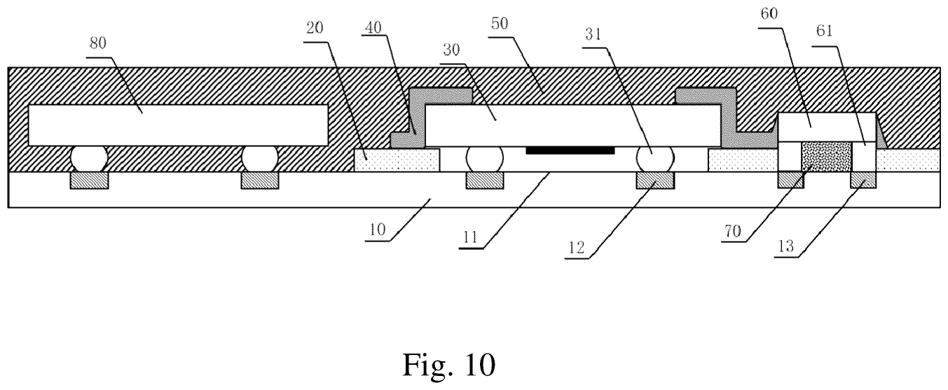

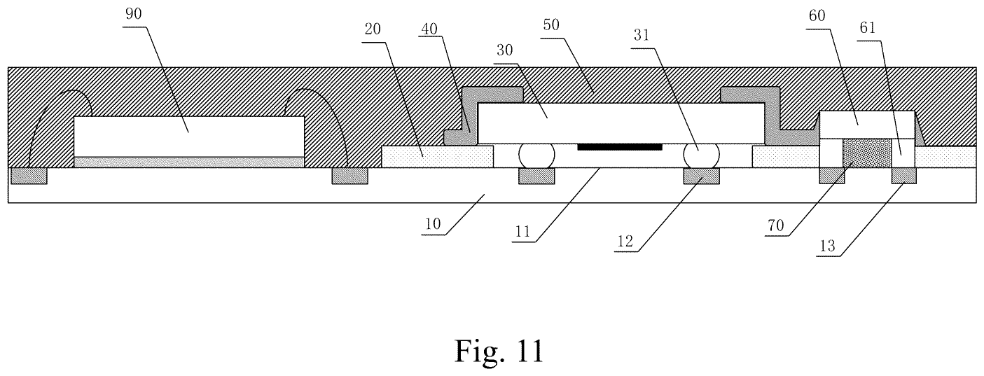

In at least one embodiment, as shown in FIGS. 10-11, the packaging structure of an RF front-end module also includes:
a first chip 80, which is flip-chip mounted on the first surface 11 of a substrate 10; and/or,
a second chip 90, which is mounted on the first surface 11 of the substrate 10, with a bonding wire on the top surface of the second chip 90, the bonding wire connects to the fourth chip pad on the substrate 10.

Here, the first chip 80 is another chip in the RF front-end module. It can be understood that the first chip 80 can be a filter chip, power amplifier chip, low-noise amplifier chip, RF switch chip, or control chip, etc. The first chip 80 is mounted on the first surface 11 of the substrate 10 using a flip-chip process.

Here, the second chip 90 is another chip in the RF front-end module. It can be understood that the second chip 90 can be a filter chip, power amplifier chip, low-noise amplifier chip, RF switch chip, or control chip, etc. A bonding wire is provided on the top surface of the second chip 90, and bonding wire connects to the fourth chip pad on the substrate 10. That is, the second chip 90 is electrically connected to the substrate 10 through a wire bonding process.

In at least one embodiment, the first adhesive part 40 at least partially covers the first chip 80 and/or second chip 90. That is, the first adhesive part 40 also at least covers the first chip 80 and/or second chip 90. For example, a spraying process can be adopted to cover all components, including the filter chip, first passive component 60, first chip 80, and second chip 90, to improve the overall efficiency of the process.

In at least one embodiment, as shown in FIGS. 10-11, the filling material 50 covers the first chip 80 and/or second chip 90. In this embodiment, the first adhesive part 40 does not cover the first chip 80 and/or second chip 90, but the filling material 50 covers the first chip 80 and/or second chip 90, ensuring better isolation of the chips.

In at least one embodiment, the packaging structure of an RF front-end module also includes:
a first chip 80, which is flip-chip mounted on a second surface of a substrate 10, where the second surface is opposite to a first surface 11; and/or,
a second chip 90, which is mounted on the second surface of the substrate 10, with a bonding wire on the top surface of the second chip 90, and the bonding wire connects to the fourth chip pad on the second surface of the substrate 10.

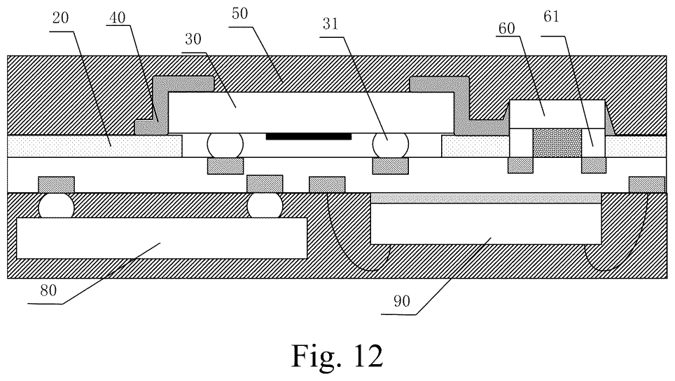

In this embodiment, the first chip 80 and/or second chip 90 are mounted on the second surface of the substrate 10, where the second surface is opposite to the first surface 11. That is, the first chip 80 and/or second chip 90 are mounted on the backside of the substrate 10 (relative to the first surface 11). As shown in FIG. 12, both the first chip 80 and second chip 90 are mounted on the second surface of the substrate 10. In at least one embodiment, the first chip 80 and/or second chip 90 are covered by the filling material 50.

At least one embodiment of this application also involves a packaging structure of an RF front-end module, which includes:
a substrate 10, with a first chip 80 pad 12 on a first surface 11;
a support structure 20, formed on the first surface 11 of the substrate 10;
a first filter chip 30, which is flip-chip mounted on the first surface 11 of the substrate 10;
a first passive component 60, which is mounted on the first surface 11 of the substrate 10, where the bottom surface of the first passive component 60 has a first conductive bump 61, which connects to the second chip 90 pad 13 on the substrate 10; and
a first adhesive part 40, which is at least partially mounted on the support structure 20, and the first adhesive part 40 covers at least part of the side surface of the first filter chip 30 and fills the space between the bottom surface of the first passive component 60 and the substrate 10.

In this embodiment, the first filter chip 30 is mounted on the first surface 11 of the substrate 10 using a flip-chip process (FC, Flip Chip).

In this embodiment, when the first adhesive part 40 is arranged, the gap formed between the first filter chip 30 and the support structure 20 is much smaller than the space between the bottom surface of the first passive component 60 and the substrate 10. Therefore, when the first adhesive part 40 is arranged, it can fill the space between the bottom surface of the first passive component 60 and the substrate 10 without passing through the gap between the first filter chip 30 and the support structure 20, or only a very small portion passes through this gap.

In this embodiment, the first adhesive part 40 is at least partially mounted to the support structure 20, covering at least part of the side surface of the first filter chip 30. This can block subsequent filling material 50 from passing through the gap between the first filter chip 30 and the support structure 20, thus forming a cavity structure between the first surface 11 of the first filter chip 30 and the substrate 10. On the other hand, the first adhesive part 40 also fills the space between the bottom surface of the first passive component 60 and the substrate 10, which can reduce the risk of failure of the first passive component 60 in subsequent processes or during use, thereby improving the overall reliability of the packaging structure.

At least one embodiment of this application also involves a packaging structure of an RF front-end module, which includes:
a substrate 10, with a first chip 80 pad 12 on a first surface 11;
a support structure 20, formed on the first surface 11 of the substrate 10;
a first filter chip 30, which is flip-chip mounted on the first surface 11 of the substrate 10, with a gap formed between the first filter chip 30 and the support structure 20;
a first adhesive part 40, which is at least partially mounted to the support structure 20 and covers at least part of the side surface of the first filter chip 30; and
a first passive component 60, which is mounted on the first surface 11 of the substrate 10, with a first conductive bump 61 on the bottom surface, and the first conductive bump 61 connects to the second chip 90 pad 13 on the substrate 10. The space between the bottom surface of the first passive component 60 and the substrate 10 is filled with a dielectric material 70.

In this embodiment, the first filter chip 30 is mounted on the first surface 11 of the substrate 10 using a flip-chip process (FC, Flip Chip). The space between the bottom surface of the first passive component 60 and the substrate 10 is filled with the dielectric material 70, which can reduce the risk of failure of the first passive component 60 and further improve the reliability of the overall packaging structure.

In at least one implementation, the first passive component 60 is electrically connected to the first filter chip 30.

At least one embodiment of this application also involves a packaging structure of an RF front-end module, which includes:
a substrate 10, with a first chip 80 pad 12 on a first surface 11;
a support structure 20, formed on the first surface 11 of the substrate 10;
a first filter chip 30, which is flip-chip mounted on the first surface 11 of the substrate 10, with a gap formed between the first filter chip 30 and the support structure 20;
a first adhesive part 40, at least partially mounted on the support structure 20 and covering at least part of the side surface of the first filter chip 30; and
a first passive component 60, which is mounted on the first surface 11 of the substrate 10, with a first conductive bump 61 on the bottom surface, and the first conductive bump 61 connects to the second chip 90 pad 13 on the substrate 10;
a filling material 50, which covers the first adhesive part 40, first filter chip 30, and at least part of the support structure 20; and
the space between the bottom surface of the first passive component 60 and the substrate 10 is filled with the first adhesive part 40 and the filling material 50.

In this embodiment, by filling the space between the bottom surface of the first passive component 60 and the substrate 10 with the first adhesive part 40 and the filling material 50, the addition of extra materials can be reduced. Since part of the space between the bottom surface of the first passive component 60 and the substrate 10 has already been filled with the first adhesive part 40, and there is the first adhesive part 40 between the filling material 50 and the substrate 10, the overall bonding strength is further increased, thereby improving the reliability of the overall packaging structure of an RF front-end module.

In at least one implementation, the height of the coverage of the first adhesive part 40 between the bottom surface of the first passive component 60 and the substrate 10 is less than half, one-third, or one-quarter of the distance between the first surface 11 of the substrate 10 and the bottom surface of the first passive component 60.

At least one embodiment of this application also involves a packaging structure of an RF front-end module, which includes:
a substrate 10, with a first chip 80 pad 12 on a first surface 11;
a support structure 20, formed on the first surface 11 of the substrate 10;
a first filter chip 30, which is mounted on the first surface 11 of the substrate 10, with a gap formed between the first filter chip 30 and the support structure 20. The bottom surface of the first filter chip 30 has a first interconnect bump 31, which connects to the first chip 80 pad 12;
a first adhesive part 40, at least partially mounted on the support structure 20, covering at least part of the side surface of the first filter chip 30;
a first passive component 60, which is mounted on the first surface 11 of the substrate 10, positioned near the first filter chip 30. The bottom surface of the first passive component 60 has a first conductive bump 61, which connects to the second chip 90 pad 13 on the substrate 10. The space between the bottom surface of the first passive component 60 and the substrate 10 is filled with a first barrier material; and
a second passive component 110, which is mounted on the first surface 11 of the substrate 10, positioned away from the first filter chip 30. The bottom surface of the second passive component 110 has a second conductive bump, which connects to the third chip pad on the substrate 10. The space between the bottom surface of the second passive component 110 and the substrate 10 is filled with a second barrier material.

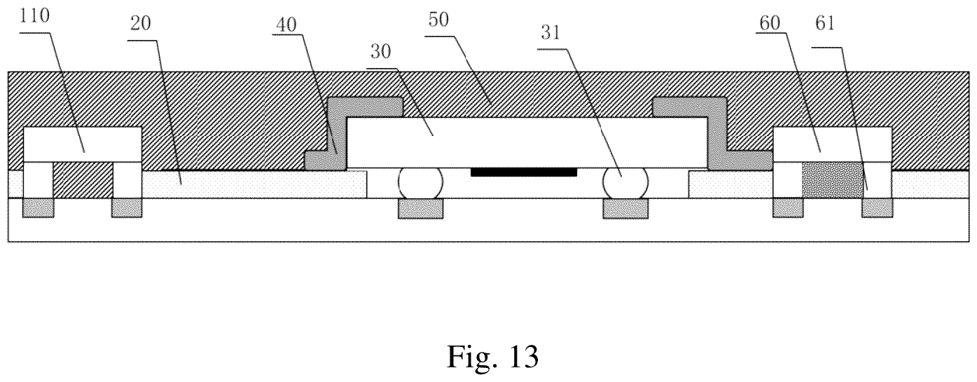

In this embodiment, as shown in FIG. 13, the packaging structure of an RF front-end module also includes the second passive component 110, which is positioned away from the first filter chip 30. The third chip pad on the first surface 11 can be arranged above (protruding from) the first surface 11 of the substrate 10 (as shown in FIG. 1), or it can be embedded in the first surface 11, or the third chip pad can be both embedded in and protruding from the first surface 11, or other feasible configurations of the third chip pad are possible and are not specifically limited here. This embodiment illustrates the third chip pad positioned on the first surface 11, as shown in FIG. 13. The first surface 11 of the substrate 10 may include one or more third chip pads. The bottom surface of the second passive component 110 is equipped with a second conductive bump, which connects to the third chip pad. The second conductive bump on the bottom surface of the second passive component 110 can be one or more. It can be understood that the number of second conductive bumps corresponds to the number of third chip pads.

In at least one implementation, the first passive component 60 is electrically connected to the first filter chip 30, while the second passive component 110 is not electrically connected to the first filter chip 30.

In at least one implementation, the space between the bottom surface of the first passive component 60 and the substrate 10 is filled with a first barrier material to improve the reliability of the first passive component 60. The space between the bottom surface of the second passive component 110 and the substrate 10 is filled with a second barrier material to improve the reliability of the second passive component 110. It can be understood that both the first barrier material and the second barrier material are dielectric material 70s.

In at least one implementation, the first barrier material and the second barrier material are different materials. In at least one implementation, the first barrier material and the second barrier material are the same material.

In at least one implementation, the packaging structure of an RF front-end module further includes:
a filling material 50, which covers the first adhesive part 40, the first filter chip 30, the first passive component 60, the second passive component 110, and at least part of the support structure 20.

In at least one implementation, the first adhesive part 40 is a fast-curing adhesive (for example, ultraviolet (UV) curing adhesive), and the first barrier material and the second barrier material are the filling material 50. In this embodiment, since the first passive component 60 is positioned near the first filter chip 30, the first adhesive part 40 is a UV-curing adhesive, which allows for rapid curing after the first adhesive part 40 is arranged, preventing it from covering the first passive component 60 near the first filter chip 30. In the subsequent step of arranging the filling material 50, the filling material 50 can enter the space between the bottom surface of the first passive component 60 and the substrate 10, as well as the space between the bottom surface of the second passive component 110 and the substrate 10, improving the reliability of both the first and second passive component 110s and reducing the need for additional process steps.

In at least one implementation, the first barrier material is a dielectric material 70, and the second barrier material is the filling material 50. The dielectric material 70 fills the space between the bottom surface of the first passive component 60 and the substrate 10. The applicant found that when the first adhesive part 40 is arranged, it may extend and cover the first passive component 60, potentially preventing the filling material 50 from filling the space between the bottom surface of the first passive component 60 and the substrate 10. This could lead to an unfilled gap between the first passive component 60 and the substrate 10, resulting in a potential risk where, during subsequent processing, the first conductive bump 61 in the first passive component 60 and the second chip 90 pad 13 may melt and cause short-circuiting between different conductive bumps, leading to failure of the circuit. Therefore, in this embodiment, by filling the space between the bottom surface of the first passive component 60 and the substrate 10 with the dielectric material 70, the possibility of this problem occurring is reduced, further improving overall reliability. Additionally, since the second passive component 110 is positioned away from the first filter chip 30, it is less likely to be covered by the first adhesive part 40. Thus, when the filling material 50 is arranged later, it can enter the space between the bottom surface of the second passive component 110 and the substrate 10.

In at least one implementation, the first barrier material is the first adhesive part 40, and the second barrier material is the filling material 50. When the first adhesive part 40 is arranged, the gap between the first filter chip 30 and the support structure 20 is much smaller than the space between the bottom surface of the first passive component 60 and the substrate 10, making it possible for the first adhesive part 40 to fill the space between the bottom surface of the first passive component 60 and the substrate 10 without extending into the gap between the first filter chip 30 and the support structure 20, or only a very small portion may do so. Moreover, since the second passive component 110 is positioned away from the first filter chip 30, it is less likely to be covered by the first adhesive part 40. Thus, when the filling material 50 is applied, it can enter the space between the bottom surface of the second passive component 110 and the substrate 10.

In at least one implementation, the first passive component 60 and/or the second passive component 110 is a surface-mount device.

In at least one implementation, the packaging structure of an RF front-end module further includes:
a first chip 80, flip-chip mounted on the first surface 11 of the substrate 10;
and/or,
a second chip 90, mounted on the first surface 11 of the substrate 10, with a bonding wire on the top surface of the second chip 90, and the bonding wire connects to the fourth chip pad on the substrate 10.

In at least one embodiment, the first adhesive part 40 covers the first filter chip 30, first chip 80, first passive component 60, and second passive component 110.

In at least one embodiment, the packaging structure of an RF front-end module further includes:
a first chip 80, which is flip-chip mounted on the second surface of the substrate 10, with the second surface being opposite to the first surface 11; and/or
a second chip 90, which is mounted on the second surface of the substrate 10, with the top surface of the second chip 90 having a bonding wire, and the bonding wire connected to the fourth chip pad on the second surface of the substrate 10.

At least one embodiment of the present application also involves a packaging structure of an RF front-end module, which includes:
a substrate 10, with a first chip 80 pad 12 positioned on a first surface 11;
a support structure 20, formed on the first surface 11 of the substrate 10;
a first filter chip 30, positioned on the first surface 11 of the substrate 10, with the bottom surface of the first filter chip 30 having a first interconnect bump 31, the first interconnect bump 31 connects to the first chip 80 pad 12;
a first adhesive part 40, which is at least partially positioned on the support structure 20 and covers at least part of the side surface of the first filter chip 30;
a first passive component 60, positioned on the first surface 11 of the substrate 10 and positioned near the first filter chip 30, with the bottom surface of the first passive component 60 having a first conductive bump 61 that connects to the second chip 90 pad 13 on the substrate 10;
a second passive component 110, positioned on the first surface 11 of the substrate 10 and positioned away from the first filter chip 30, with the bottom surface of the second passive component 110 having a second conductive bump that connects to the third chip pad on the substrate 10;
a filling material 50, which covers at least the first adhesive part 40, the first filter chip 30, and at least part of the support structure 20; and
the space between the first passive component 60 and the substrate 10 is filled with the first adhesive part 40 and the filling material 50, while the space between the second passive component 110 and the substrate 10 is filled with the filling material 50.

At least one embodiment of the present application also involves a packaging structure of an RF front-end module, which includes:
a substrate 10, with a first chip 80 pad 12 positioned on a first surface 11;
a support structure 20, formed on the first surface 11 of the substrate 10;
a first filter chip 30, positioned on the first surface 11 of the substrate 10, with a gap formed between the first filter chip 30 and the support structure 20, and the bottom surface of the first filter chip 30 having a first interconnect bump 31, which connects to the first chip 80 pad 12;
a first passive component 60, positioned on the first surface 11 of the substrate 10 with a distance of d1 from the first filter chip 30, and the bottom surface of the first passive component 60 having a first conductive bump 61 that connects to the second chip 90 pad 13 on the substrate 10, with the space between the bottom surface of the first passive component 60 and the substrate 10 being filled with a first barrier material;
a first adhesive part 40, which is at least partially positioned on the support structure 20 and covers at least part of the side surface of the first filter chip 30, filling the space between the bottom surface of the first passive component 60 and the substrate 10;
a third passive component 100, positioned on the first surface 11 of the substrate 10 with a distance of d3 from the first filter chip 30, the bottom surface of the third passive component 100 is provided with a third conductive bump, which connects to the fourth chip pad on the substrate 10, and the space between the bottom surface of the third passive component 100 and the substrate 10 is filled with a dielectric material 70;
where d3 is greater than or equal to d1.

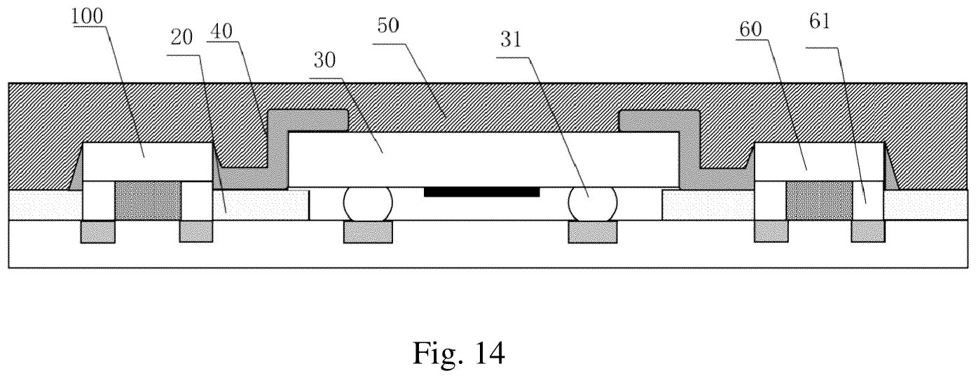

In at least one embodiment, the third passive component 100 can be a passive element, such as a capacitor, inductor, or resistor. As shown in FIG. 14, the third passive component 100 is arrange on the first surface 11 of the substrate 10. The bottom surface of the third passive component 100 is provided with a third conductive bump, which connects to the fourth chip pad on the substrate 10, and the space between the bottom surface of the third passive component 100 and the substrate 10 is filled with a dielectric material 70. The distance “d3” between the third passive component 100 and the first filter chip 30 is greater than or equal to the distance “d1” between the first passive component 60 and the first filter chip 30.

In at least one embodiment, d1 is less than 150 μm, 120 μm, 100 μm, or 80 μm.

In at least one embodiment, d3 is less than 200 μm, 180 μm, or 150 μm.

In at least one embodiment, d1 is less than 150 μm, and/or d3 is less than 200 μm.

In at least one embodiment, the packaging structure of an RF front-end module further includes:
a second passive component 110, mounted on the first surface 11 of the substrate 10 with a distance of d2 from the first filter chip 30, the bottom surface of the second passive component 110 is provided with a second conductive bump, which connects to the third chip pad on the substrate 10, and the space between the bottom surface of the second passive component 110 and the substrate 10 is filled with a filling material 50;
where d2 is greater than d3.

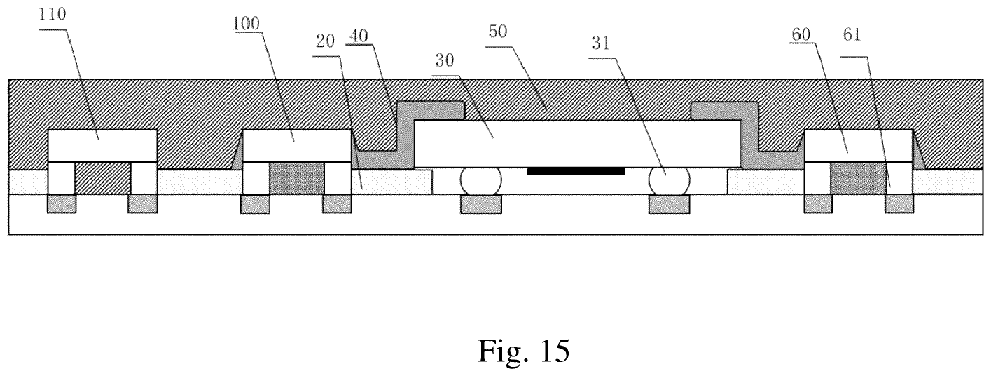

As shown in FIG. 15, the second passive component 110 is arranged on the first surface 11 of the substrate 10. The bottom surface of the second passive component 110 has a second conductive bump, which connects to the third chip pad on the substrate 10. The space between the bottom surface of the second passive component 110 and the substrate 10 is filled with a filling material 50. The distance “d2” between the second passive component 110 and the first filter chip 30 is greater than the distance “d3” between the third passive component 100 and the first filter chip 30.

In at least one embodiment, d2 is greater than 180 μm, 200 μm, 220 μm, or 250 μm.

In this embodiment, because the distance between the second passive component 110 and the first filter chip 30 is larger, it will not be affected by the first adhesive part 40 positioned near the first filter chip 30. Therefore, when filling material 50 is arranged at the later step, it can smoothly fill the space between the bottom surface of the second passive component 110 and the substrate 10, forming a barrier and improving the reliability of the second passive component 110.

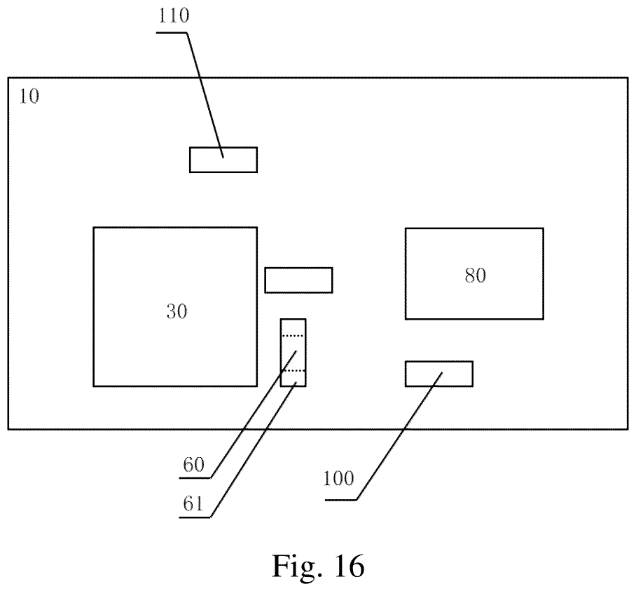

In one embodiment, as shown in FIG. 16, this is a top-down schematic diagram of the packaging structure of an RF front-end module. On the first surface 11 of the substrate 10, the first passive component 60 is positioned near the first filter chip 30, while the second passive component 110 100 is placed farthest from the first filter chip 30. The distance “d3” between the third passive component 100 110 and the first filter chip 30 lies between d1 and d2.

It can be understood that in FIG. 16, the position or angle of arrangement of the first passive component 60 is merely an example. For instance, the first passive component 60 can be rotated 90 degrees and positioned near the first filter chip 30 (similar to the component arranged above the first passive component 60 in FIG. 6).

In at least one embodiment, the first barrier material is a part of the first adhesive part 40, or the first barrier material is a dielectric material 70.

At least one embodiment of the present application also involves a packaging structure of an RF front-end module, which includes:
a substrate 10, including a first surface 11 and a second surface, with the first surface 11 being opposite to the second surface;
a first support structure 20, formed on the first surface 11 of the substrate 10;
a second support structure 20, formed on the second surface of the substrate 10;
at least one first filter chip 30, flip-chip mounted on the first surface 11 of the substrate 10;
a first adhesive part 40, at least partially positioned on the first support structure 20 and covering at least part of the side surface of the first filter chip 30;
at least one second filter 120 chip, flip-chip mounted on the second surface of the substrate 10; and
a first passive component 60, positioned on the substrate 10 and located near any first filter chip 30 or second filter 120 chip, the bottom surface of the first passive component 60 is provided with a first conductive bump 61, which connects to the second chip 90 pad 13 on the substrate 10, and the space between the bottom surface of the first passive component 60 and the substrate 10 is filled with a first barrier material.

In this embodiment, at least one first filter chip 30 is positioned on the first surface 11 of the substrate 10, and at least one second filter 120 chip is positioned on the second surface of the substrate 10. The second filter 120 chip can be a Surface Acoustic Wave (SAW) filter chip, a Bulk Acoustic Wave (BAW) filter chip, or other filter chips requiring a cavity.

The first passive component 60 is positioned on the substrate 10 near any first filter chip 30 or any second filter 120 chip. It can be understood that if the first passive component 60 is positioned on the first surface 11 of the substrate 10, the corresponding second chip 90 pad 13 is also located on the first surface 11. If the first passive component 60 is positioned on the second surface of the substrate 10, the corresponding second chip 90 pad 13 is positioned on the second surface.

In at least one embodiment, a gap is formed between the second filter 120 chip and the second support structure 20.

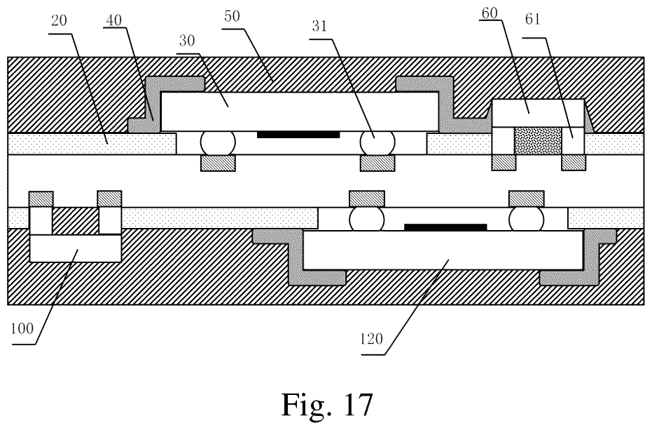

For example, as shown in FIG. 17, the first passive component 60 is positioned near the first filter chip 30. The bottom surface of the first passive component 60 has a first conductive bump 61, which connects to the second chip 90 pad 13 on the substrate 10, and the space between the bottom surface of the first passive component 60 and the substrate 10 is filled with a first barrier material.

In at least one embodiment, the packaging structure of an RF front-end module further includes:
a second passive component 110, mounted on the substrate 10 and arranged away from any first filter chip 30 and any second filter 120 chip, the bottom surface of the second passive component 110 is provided with a second conductive bump, which connects to the third chip pad on the substrate 10. The space between the bottom surface of the second passive component 110 and the substrate 10 is filled with a second barrier material.

As shown in FIG. 17, the second passive component 110 100 is arranged on the substrate 10 and away from any first filter chip 30 60 and any second filter 120 chip 120.

In at least one embodiment, the first adhesive part 40 is an UV-curable adhesive. The first barrier material and the second barrier material are filling material 50s.

In at least one embodiment, the first barrier material is a dielectric material 70, and the second barrier material is a filling material 50.

In at least one embodiment, the first barrier material is first adhesive part 40, and the second barrier material is filling material 50.

In at least one embodiment, the packaging structure of an RF front-end module further includes:
a first chip 80, flip-chip mounted on the first surface 11 or the second surface of the substrate 10; and/or,
a second chip 90, mounted on the first surface 11 or the second surface of the substrate 10, with a bonding wire on the top surface of the second chip 90, the bonding wire connects to the fourth chip pad on the substrate 10.

In at least one embodiment, the first adhesive part 40 covers at least part of the first chip 80 and/or second chip 90.

At least one embodiment of the present application also involves a packaging structure of an RF front-end module, which includes:
a substrate 10, including a first surface 11 and a second surface, with the first surface 11 being opposite to the second surface;
a first support structure 20, formed on the first surface 11 of the substrate 10;
a second support structure 20, formed on the second surface of the substrate 10;
at least one first filter chip 30, flip-chip mounted on the first surface 11 of the substrate 10;
a first adhesive part 40, at least partially arranged on the first support structure 20 and covering at least part of the side surface of the first filter chip 30;
at least one second filter 120 chip, flip-chip mounted on the second surface of the substrate 10;
a filling material 50, covering the first adhesive part 40, the first filter chip 30, and at least part of the first support structure 20; and
a first passive component 60, arranged on the substrate 10 and positioned near any first filter chip 30, the bottom surface of the first passive component 60 is provided with a first conductive bump 61, which connects to the second chip 90 pad 13 on the substrate 10, and the space between the bottom surface of the first passive component 60 and the substrate 10 is filled with the first adhesive part 40 and filling material 50.

At least one embodiment of the present application also involves a packaging structure of an RF front-end module, which includes:
a substrate 10, including a first surface 11 and a second surface, with the first surface 11 being opposite to the second surface;
a first support structure 20, formed on the first surface 11 of the substrate 10;
a second support structure 20, formed on the second surface of the substrate 10;
at least one first filter chip 30, flip-chip mounted on the first surface 11 of the substrate 10;
at least one second filter 120 chip, flip-chip mounted on the second surface of the substrate 10;
a second adhesive part 41, at least partially arranged on the second support structure 20 and covering at least part of the side surface of the second filter 120 chip;
a filling material 50, covering the second adhesive part 41, at least one second filter 120 chip, and at least part of the second support structure 20; and
a first passive component 60, arranged on the substrate 10 and positioned near any second filter 120 chip, the bottom surface of the first passive component 60 is provided with a first conductive bump 61, which connects to the second chip 90 pad 13 on the substrate 10, and the space between the bottom surface of the first passive component 60 and the substrate 10 is filled with the second adhesive part 41 and filling material 50.

In at least one embodiment, the electrical connection of the substrate 10 in the packaging structure of an RF front-end module can be achieved through metal balls, metal pillars, or intermediary layers (interposers) with internal wiring, but these methods are not specifically limited here.

Optionally, the second filter 120 chip can be a Surface Acoustic Wave (SAW) filter chip, a Bulk Acoustic Wave (BAW) filter chip, or other filter chips requiring a cavity.

In at least one embodiment, the first filter chip 30 is a Surface Acoustic Wave (SAW) filter chip or a Bulk Acoustic Wave (BAW) filter chip; and/or, the second filter 120 chip is a Surface Acoustic Wave (SAW) filter chip or a Bulk Acoustic Wave (BAW) filter chip.

To avoid redundancy, certain details of similar or identical technical features in the above description may not be explicitly stated in some embodiments or implementations. However, these details are equally applicable across different embodiments or implementations.

Understandably, to avoid redundancy, details of certain identical or similar technical features in the above description may not be elaborated upon in some embodiments or implementations. However, it should be noted that these details are essentially applicable to different embodiments or implementations.

The above are merely the preferred embodiments of this application, and are not intended to limit the application. Any modification, equivalent substitution and improvement made within the spirit and principle of this application shall be included in the protection scope of this application.

What is claimed is:

1. A packaging structure of an RF front-end module, comprising:
a substrate, wherein a first chip pad is mounted on a first surface;
a support structure, wherein the support structure is formed on the first surface of the substrate;
a first filter chip, wherein the first filter chip is mounted on the first surface of the substrate, a bottom surface of the first filter chip is provided with a first interconnect bump, the first interconnect bump is connected with the first chip pad, and a cavity structure is formed between the first filter chip and the substrate;
a first adhesive part, wherein the first adhesive part is at least partially mounted on the support structure and covers at least part of a side surface of the first filter chip; and
a filling material, wherein the filling material covers the first adhesive part, the first filter chip and at least part of the support structure.

2. The packaging structure of an RF front-end module of claim 1, wherein the first adhesive part covers at least part of the side surface of the first filter chip and extends to a top surface of the first filter chip, and the top surface of the first filter chip is opposite to the bottom surface of the first filter chip; or
the first adhesive part extends from the support structure to a gap formed between the first filter chip and the support structure.

3. The packaging structure of an RF front-end module of claim 1, further comprising:
a second adhesive part, wherein the second adhesive part at least partially covers the top surface of the first filter chip.

4. The packaging structure of an RF front-end module of claim 3, wherein the second adhesive part comprises at least two parts mounted at intervals on the top surface of the first filter chip.

5. The packaging structure of an RF front-end module of claim 1, further comprising:
a first passive component, wherein the first passive component is mounted on the first surface of the substrate, a first conductive bump is mounted on a bottom surface of the first passive component, and the first conductive bump is connected with a second chip pad on the substrate.

6. The packaging structure of an RF front-end module of claim 5, wherein the first passive component is mounted adjacent to the first filter chip, and the first adhesive part of the packaging structure of an RF front-end module is a rapid-curing adhesive; and a space between the bottom surface of the first passive component and the substrate is filled with the filling material or a dielectric material.

7. The packaging structure of an RF front-end module of claim 5, wherein the first adhesive part of the packaging structure of an RF front-end module or the filling material of the packaging structure of an RF front-end module fills the space between the bottom surface of the first passive component and the substrate.

8. The packaging structure of an RF front-end module of claim 5, wherein the first adhesive part also at least partially covers a top surface or a side surface of the first passive component, and the top surface of the first passive component is opposite to the bottom surface of the first passive component.

9. The packaging structure of an RF front-end module of claim 5, wherein an area of the first adhesive part covering the side surface of the first passive component is less than half of an area of the side surface of the first passive component, and/or, a maximum height of the first adhesive part covering the side surface of the first passive component is less than half a height of the side surface of the first passive component.

10. The packaging structure of an RF front-end module of claim 1, wherein projections of the first filter chip and the support structure overlap in the longitudinal direction.

11. The packaging structure of an RF front-end module of claim 1, wherein a gap is formed between the first filter chip and the support structure; the gap formed between the first filter chip and the support structure is less than or equal to 10 μm.

12. The packaging structure of an RF front-end module of claim 1, further comprising:
a first chip, wherein the first chip is flip-chip mounted on the first surface of the substrate;
and/or,
a second chip, wherein the second chip is mounted on the first surface of the substrate, a bonding wire is mounted on a top surface of the second chip, and the bonding wire is connected with a fourth chip pad on the substrate; and
the filling material covers the first chip and/or the second chip.

13. A packaging structure of an RF front-end module, comprising:
a substrate, wherein a first chip pad is mounted on the first surface;
a support structure, wherein the support structure is formed on the first surface of the substrate;
a first filter chip, wherein the first filter chip is mounted on the first surface of the substrate, and a first interconnect bump is mounted on a bottom surface of the first filter chip, and the first interconnect bump is connected with the first chip pad;
a first adhesive part, wherein the first adhesive part is at least partially mounted on the support structure and covers at least part of a side surface of the first filter chip;
a first passive component, wherein the first passive component is mounted on the first surface of the substrate and adjacent to the first filter chip, a bottom surface of the first passive component is provided with a first conductive bump, the first conductive bump is connected with the second chip pad on the substrate, and a first barrier material is filled between the bottom surface of the first passive component and the substrate; and
a second passive component, wherein the second passive component is mounted on the first surface of the substrate and away from the first filter chip, a bottom surface of the second passive component is provided with a second conductive bump, the second conductive bump is connected with a third chip pad on the substrate, and a second barrier material is filled between the bottom surface of the second passive component and the substrate.

14. The packaging structure of an RF front-end module of claim 13, further comprising:
a filling material, wherein the filling material covers the first adhesive part, the first filter chip, the first passive component, the second passive component, and at least part of the support structure.

15. The packaging structure of an RF front-end module of claim 13, further comprising:
a first chip, wherein the first chip is flip-chip mounted on the first surface of the substrate;
and/or,
a second chip, wherein the second chip is mounted on the first surface of the substrate, a bonding wire is mounted on a top surface of the second chip, and the bonding wire is connected with a fourth chip pad on the substrate.

16. The packaging structure of an RF front-end module of claim 15, wherein the first adhesive part covers the first filter chip, the first chip, the first passive component, and the second passive component.

17. A packaging structure of an RF front-end module, comprising:
a substrate, wherein a first chip pad is mounted on a first surface;
a support structure, wherein the support structure is formed on the first surface of the substrate;
a first filter chip, wherein the first filter chip is mounted on the first surface of the substrate, a first interconnect bump is mounted on a bottom surface of the first filter chip, and the first interconnect bump is connected with the first chip pad;
a first passive component, wherein the first passive component is mounted on the first surface of the substrate with a distance “d1” from the first filter chip, and a first conductive bump is mounted on a bottom surface of the first passive component, the first conductive bump is connected with the second chip pad on the substrate, and a first barrier material is filled between the bottom surface of the first passive component and the substrate;
a first adhesive part, wherein the first adhesive part is at least partially mounted on the support structure, and the first adhesive part covers at least part of a side surface of the first filter chip;
a third passive component, wherein the third passive component is mounted on the first surface of the substrate with a distance “d3” from the first filter chip, and a third conductive bump is mounted on a bottom surface of the third passive component, the third conductive bump is connected with a fourth chip pad on the substrate, and a dielectric material is filled between the bottom surface of the third passive component and the substrate;
where d3 is greater than or equal to d1.

18. The packaging structure of an RF front-end module of claim 17, further comprising:
a second passive component, wherein the second passive component is mounted on the first surface of the substrate with a distance “d2” from the first filter chip, and a second conductive bump is mounted on a bottom surface of the second passive component, the second conductive bump is connected with a third chip pad on the substrate, and a filling material is filled between the bottom surface of the second passive component and the substrate;
wherein d2 is greater than d3.

19. The packaging structure of an RF front-end module of claim 17, wherein the first barrier material is a part of the first adhesive part, or the first barrier material is a dielectric material.

20. The packaging structure of an RF front-end module of claim 17, wherein d1 is less than 150 μm, and/or d3 is less than 200 μm.
